(19) United States
(12) Patent Application Publication
(10) Pub. No.: US 2018/0062757 A1
(43) Pub. Date: Mar. 1, 2018

(54) COHERENT RECEIVER

(71) Applicant: Sumitomo Electric Device Innovations, Inc., Yokohama-shi (JP)

(72) Inventor: Junji Watanabe, Yokohama-shi (JP)

(21) Appl. No.: 15/556,711

(22) PCT Filed: Mar. 7, 2016
(86) PCT No.: PCT/JP2016/056912

§ 371 Date: Sep. 8, 2017

(30) Foreign Application Priority Data
Mar. 9, 2015 (JP) 2015-046196

(51) Int. Cl. H04B 10/61; H01L 31/0232

(52) U.S. Cl. CPC H04B 10/614; G02F 2002/006; H01L 31/02327; H04B 10/6151

(57) ABSTRACT

The coherent receiver includes a housing, a first multi-mode interference device that includes a first local light input port and a first signal light input port, a second multi-mode interference device that includes a second local light input port and a second signal light input port, a first splitter, a first reflector, a second splitter, a second reflector, and a mounting area on an optical path between the first splitter and the firs local light input port, where the mount area mounts an attenuator for the signal light that attenuates a magnitude of a portion of the local light.

### TECHNICAL FIELD

The present invention relates to a coherent receiver.

### BACKGROUND ART

A Japanese Patent Application laid open No. H05-0828 10A has disclosed an optical-to-electrical conversion apparatus. This patent document has disclosed an arrangement of a coherent receiver.

### SUMMARY OF INVENTION

A coherent receiver provides a multi-mode interference device where the multi-mode interference (MMI) device includes, for instance, two MMI elements. The coherent receiver may demodulate signal light entering the two MMI elements with local light concurrently entering the MMI elements. When alignment accuracy of optical components, such as an optical splitter, is degraded during an assembly thereof, the local light and the signal light entering the two MMI devices differ magnitudes thereof, which possibly increases an error rate during the demodulation.

### Means for Solving Subject

The coherent receiver according to the present invention extracts phase information involved in signal light that contains two polarizations by interfering between the signal light and local light. The coherent receiver of the present invention includes a polarization beam splitter (PBS) that splits the signal light into two portions, a beam splitter (BS) that splits the local light into two portions, a first multi-mode interference (MMI) device that interferes between one of the two portions of the signal and another of the two portions of the local light, and a second MMI device that interferes between the another of the two portions of the signal light and one of the two portions of the local light. Moreover, the coherent receiver provides at least one optical attenuator disposed on an optical path of the one of the two portions of the local light or on an optical path of the one of the two portions of the signal light, the at least one optical attenuator attenuating the one of the two portions of the local light or the one of the two portions of the signal light.

The present invention may equalize the magnitude of the one of the two portions of the local light entering the first MMI device with the magnitude of the another of the two portions of the local light entering the second MMI device, or equalize the magnitude of the one of the two portions of the signal light entering the second MMI device with the magnitude of the another of the two portions of the signal light entering the first MMI device.

### BRIEF DESCRIPTION OF DRAWINGS

FIG. 1 is a plan view schematically showing a coherent receiver according to the first embodiment of the present invention.

FIG. 2 is a perspective view showing an inside of the coherent receiver of the first embodiment.

FIGS. 3A to 3D schematically show an area where an optical ATT is mounted therein.

FIGS. 4A to 4D schematically show an area for mounting the optical attenuator according to the first modification.

FIGS. 5A and 5B schematically show an area for mounting the optical attenuator according to the second modification.

FIGS. 6A and 6B schematically show an area for mounting the optical attenuator according to the third modification.

FIGS. 7A to 7D schematically show an area for mounting the optical attenuator according to the fourth modification.

FIGS. 8A and 8B schematically show an area for mounting the optical attenuator according to the fifth modification.

FIGS. 9A and 9B schematically show an area for mounting the optical attenuator according to the sixth modification.

FIGS. 10A and 10B schematically show a process of assembling the coherent receiver of the present invention.

FIG. 11 shows a process of assembling the coherent receiver of the present invention.

FIG. 12 shows a process of assembling the coherent receiver of the present invention.

FIG. 13 schematically shows procedures of assembling the coherent receiver of the present invention.

FIG. 14 shows a process of assembling the coherent receiver of the present invention.

FIG. 15 shows a process of assembling the coherent receiver of the present invention.

FIG. 16 shows a process of assembling the coherent receiver of the present invention.

FIG. 17 shows a process of assembling the coherent receiver of the present invention.

FIG. 18 shows a process of assembling the coherent receiver of the present invention.

FIG. 19 shows a behavior of an attenuation of the optical attenuator against a bias supplied thereto.

FIG. 20 shows a process of assembling the coherent receiver of the present invention.

FIG. 21 shows a process of assembling the coherent receiver of the present invention.

FIG. 22 shows a process of assembling the coherent receiver of the present invention.

FIGS. 23A to 23D show coupling tolerances of respective lenses in the two lens system.

### DESCRIPTION OF EMBODIMENT

Next, a coherent receiver and a process of assembling the same according to embodiment of the present invention will be described. The present invention is not restricted to the embodiment, and includes those defined in claims and all modifications done within a range of the claims and equivalents thereof. The description below omits duplicating explanations for elements same with or similar to each other by assigning numerals or symbols same with or similar to each other.

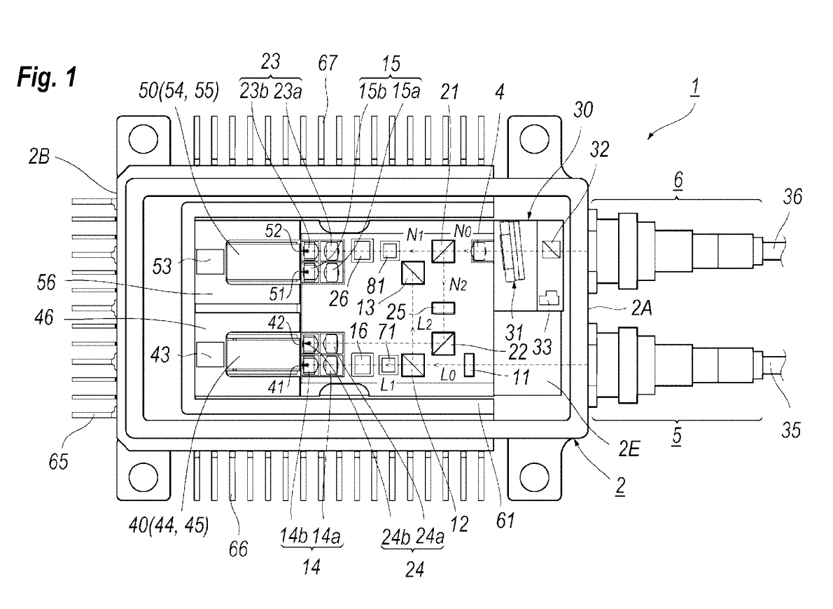

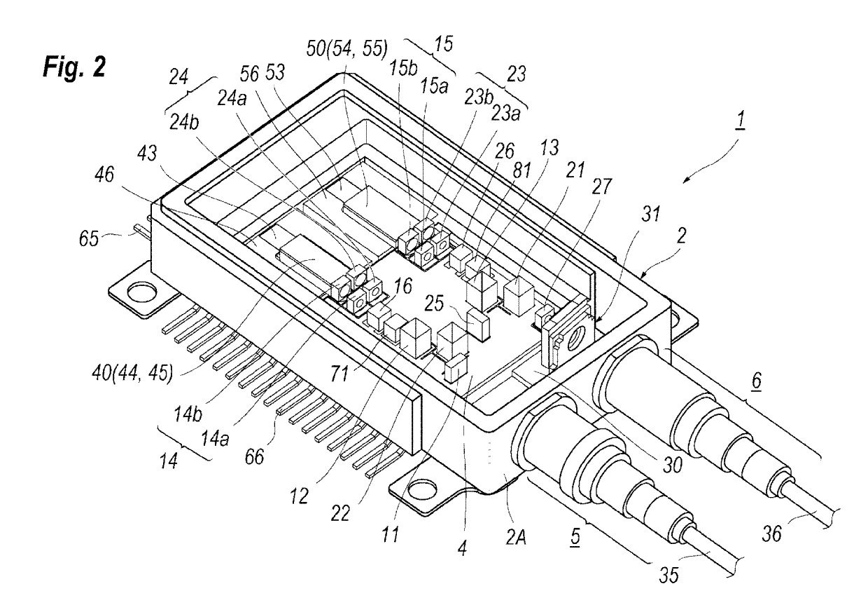

FIG. 1 is a plan view schematically illustrating a coherent receiver 1 according to the first embodiment of the present invention. FIG. 2 is a perspective view showing an inside of the coherent receiver shown in FIG. 1. The coherent receiver 1 recovers information contained in the signal light modulated in a phase thereof by interfering between local light (Local beam: Lo) and the signal light (Signal beam: Sig). The recovered information is externally output after converting them into electrical signals.

The coherent receiver 1 provides optical systems corresponding to the local light and the signal light, respectively; two multi-mode interfering (MMI) devices, 40 and 50; and a housing 2 that installs the optical systems and the MMI devices, 40 and 50, therein. The housing 2 in a bottom 2E thereof mounts optical components and two MMI devices, 40 and 50, thereon through a carrier 3 and a base 4. The carrier 3 also mounts circuit boards, 46 and 56, on which circuits that processes recovered information are mounted. The carrier 3 may be made of metal, typically copper tungsten (CuW), while, the base 4 may be made of insulating material such as alumina (Al₂O₃), aluminum nitride (AlN) and so on. Two MMI devices, 40 and 50, are made of semiconductor material such as indium phosphide (InP). The MMI devices, 40 and 50, each provide Lo beam input ports, 41 and 51, and Sig beam input ports, 42 and 52, where the Lo light input to the Lo beam input ports, 41 and 51, are interfered with the Sig light input to the Sig light input ports, 42 and 52, to recover the phase information. Two MMI devices, 40 and 50, are independently prepared or, integrated with each other.

The housing 2 provides a first side wall (a front wall) 2A. The explanation below assumes that a side where the front wall 2A is provided is a “front”; while, another side is “rear”. However, those assumptions of the front/rear are merely for the explanation sake and could not restrict the scope of the present invention. The front wall 2A fixes Lo light input port 5 and a Sig light input port 6 thereto by, for instance, laser welding. The Lo light enters the Lo light input port 5 from a polarization maintaining fiber (PMF) 35, while, the Sig light enters the Sig light input port 6 from a single mode fiber (SMF) 36. Two input ports, 5 and 6, each assemble collimating lenses to transform the Lo light and the Sig light, which are dispersive beams just output from the respective fibers, into respective collimated beams, and provide the collimated beams within the housing 2.

One of the optical systems for the Lo beam couples the Lo light provided from the Lo light input port 5 with the Lo beam input ports, 41 and 51, of the MMI devices, 40 and 50. Specifically, the optical system for the Lo beam includes a polarizer 11, a first beam splitter (BS) 12, a first mirror 13, and a couple of lens systems, 14 and 15, each including first lenses, 4B 14b and 5B 15b, disposed relatively closer to the MMI devices, 40 and 50, and second lenses, 14a and 15a, disposed relatively apart from the MMI devices, 40 and 50. The polarizer 11, which optically couples with the Lo light input port 5, polarizes the Lo light provided from the Lo light input port 5. An optical source for the Lo light generally outputs the Lo light with extremely flat elliptical polarization. Even the optical source generates Lo light with linear polarization; the Lo light (L₀) just provided from the Lo light input port 5 does not always align the direction of the polarization with a designed direction. The polarizer 11 may convert the Lo light into a linear polarization whose direction is aligned with a designed direction, for instance, parallel to the bottom 2E of the housing 2.

The first BS 12 splits the Lo light L₀ provided from the polarizer 11 with a split ratio of 50:50. One of the Lo light L₁ split thereby advances straight in the first BS 12 and heads the first MMI device 40. Another Lo light L₂, whose optical axis is converted by 90° by the first BS 12 and further by 90° again by the first reflector 13, hades the second MMI device 50. The embodiment of FIG. 1 implements the first BS 12 with a prism type and the first reflector 13 also with a prism type, where the prism type attaches two prisms and an optical splitting facet or an optical reflecting facet is formed in the interface between the two prisms. However, the first BS 12 and the first reflector 13 are not restricted to the prism type. The first BS 12 and the first reflector 13 may adopt, what is called, a parallel plate type.

The optical system for the Lo light may further implements a couple of the lens systems, 14 and 15, the first skew adjusting device 16, and the first optical attenuator 71. The lens system 14, which is placed between the first BS 12 and the first MMI device 40, couples the Lo light L₁ transmitting the first BS 12 with the Lo beam input port 41 of the first MMI device 40. The lens system 15, which is placed between the first reflector 13 and the second MMI device 50, optically couples the Lo light L₂ reflected by the first reflector 13 with the Lo beam input port 51 of the second MMI device 50. The skew adjusting device 16, which is placed between the first BS 12 and the lens system 14, may compensate a difference in optical distances from the first BS 12 to the respective Lo beam input ports, 41 and 51, with respect to the two Lo light, L₁ and L₂, split by the first BS 12. That is, the optical distance for the Lo light L₁ is shorter that the optical distance for the Lo light L₂ by a length from the first BS 11 to the first reflector 13. The first skew adjusting device 16 may compensate this difference. In other words, the first skew adjusting device 16 may compensate a time difference for the Lo light at the respective Lo beam input ports, 41 and 51. The first skew adjusting device 16 is made of silicon (Si) and has transmittance about 99% for the Lo light, which means that the first skew adjusting device 16 is substantially transparent for the Lo light.

In the optical path for the Lo light, a path from the first BS 12 to the first MMI device 40 for one of the Lo light L₁ is sometimes assumed to the first optical path, while, another path to the second MMI device 50 for the other Lo light L₂ is sometimes called as the second optical path. As described in a latter half of the present specification, the first optical path in a state without the optical attenuator (NIT) 71 has optical coupling efficiency with the Lo beam input port 41 that is greater than coupling efficiency with the Lo beam input port 51 of the second optical path.

The optical system for the Sig light includes the second BS 21, the second reflector 22, and a couple of lens systems, 23 and 24. The second BS 21, which optically couples with the signal light input port 6, splits the Sig light provided from the single mode fiber 36 through the signal light input port 6. The split ratio is fundamentally set to be 50:50. The Sig light provided from the single mode fiber 36 in the polarization thereof is indefinite. The second BS 21 splits this Sig light N₀ depending on the polarization thereof. For instance, the second BS 21 transmits a pollarization component of the Sig light N₀ that is parallel to the bottom 2E of the housing, which becomes one of the Sig light N₁; while, reflects another pollarization component of the Sig light that is perpendicular to the bottom 2E, which becomes another Sig light N₂. Accordingly, the second BS 21 may be a polarization beam splitter (PBS).

The optical system of the Sig light further includes a couple of lens systems, 23 and 24, a skew adjusting device 26, and a half wavelength (λ/2) plate 25. The Sig light N₁ passing the PBS 21 optically couples with the Sig beam input port of the second MMI device 50 by the lens system 23 after passing the second skew adjusting device 26. The second skew adjusting device 26 compensates optical paths for the Sig light, N₁ and N₂, from the PBS 21 to the second reflector 22. That is, the Sig light N₂ reaches the first MMI device 40 after propagating on an optical path longer than that of the Sig light N₁ to the second MMI device 50 by a distance from the PBS 21 to the second reflector 22. The skew adjusting device 26 may set a delay corresponding to this optical path for the Sig light N₁.

The other Sig light N₂ reflected by the PBS 21 rotates the polarization thereof by 90° duaring passage through the λ/2 plate 25. That is, the Sig light No is split into two Sig light, N₁ and N₂, depending of the polarization thereof. The two Sig light just after the splitting have respective polarizations perpendicular to each other. Passing the λ/2 plate 25, the Sig light N₂ rotates the polarization thereof by 90°, which becomes identical with the polarization of the other Sig light N₁. The Sig light N₂ optically couples with the Sig beam input port 42 of the first MMI device 40 through the lens system 24 after rotating the optical axis thereof by 90° by the second reflector 22. FIG. 1 also illustrates the PBS 21 and the second reflector 22 with the prism type that attaches two prisms and shows the function of the beam splitting depending on the polarization and the beam reflection at the interface between the two prisms; however, the PBS 21 and the second reflector 22 may have the arrangement of the parallel plate type where the function of the beam splitting and the beam reflection is realized in a surface of the parallel plate. Similar to the lens systems, 14 and 15, for the Lo light, the lens systems, 23 and 24, also provides first lenses, 23b and 23b, placed closer to the MMI devices, 40 and 50, and second lenses, 23a and 24a, placed relatively apart from the MMI devices, 40 and 50. The lens systems, 23 and 24, may enhance the optical coupling efficiency of the Sig light, N₁ and N₂ for the Sig beam input ports, 42 and 52, respectively, by the combination of the first and second lenses, 23b and 23a, and 24b and 24a.

An optical path from the PBS 22 to the Sig beam input port 52 of the second MMI device 50, which is for the Sig light N₁, may be called as the third optical path, while, another optical path from the PBS 22 to the Sig beam input port 42 of the first MMI device 40, which is for the Sig light N₂, may be called as the fourth optical path. The coherent recver 1 of the present embodiment may interpose the second optical ATT 81 between the skew adjusting device 26 and the PBS 22. The optical coupling efficiency of the third optical pass is greater than that of the fourth optical path in a status where the third optical path omits the second ATT 81.

The first MMI device 40 includes a multi-mode interference waveguide (MMI waveguide) 44 and a photodiode (PD) optically coupled with the MMI waveguide 44. The MMI waveguide 44, which is formed on, for instance, a semiconductor substrate made of indium phosphide (InP), may recover a phase component of the Sig light N₂ coincident with the phase of the Lo light L₁ input to the Lo beam input port 41 and another phase component of the Sig light N₂ that is different from the phase of the Lo light L₁ by 90° independent of the former phase component. That is, the first MMI device 40 may recover two data independent to each other from the Sig light N₂. Similarly, the second MMI device 50 includes two MMI waveguides 54 and a PD 55 optically coupled with the two MMI waveguides 54. The two MMI waveguides 54, which are also formed on the semiconductor substrate made of InP, may recover two data by interfering the Sig light N₁ entering the Sig beam input port 51 with the Lo light L₂ entering the Lo beam input port 52.

The coherent receiver 1 according to the present embodiment provides the housing 2 that includes a first side wall 2A, which may be a front wall, and a second side wall 2B opposite to the first side wall 2A, which may be a rear wall. Also, the housing 2 provides feedthroughs 61 in the rear wall 2B and other two side walls connecting the front wall 2A with the rear wall 2B. The feedthrough 61 in the rear wall 2B provides a plurality of signal output terminals 65 that outputs total four data recovered by the two MMI devices, 40 and 50, independently to the outside of the coherent receiver 1 after processed by the ICs, 43 and 53. Two side walls provide other terminals 66. These terminals 66 primarily provide signals into the housing 2, where those signals are for driving two MMI devices, 40 and 50, those for driving respective optical components, and so on, where those signals are DC signals or have low frequencies. The first and second ICs, 43 and 53, are mounted on circuit boards, 46 and 56, on the base 4 so as to surround the MMI devices, 40 and 50, respectively. The circuit boards, 46 and 56, also mount resistors, capacitors, and so on, or if necessary, DC/DC converters.

The coherent receiver 1 of the present embodiment provides mounting areas, 70 and 80 in the first and third optical paths, respectively, where those mounting areas, 70 and 80, that mount the optical ATTs, 71 and 81. When the optical coupling efficiency of the first optical pather with the first MMI device 40 is greater than the optical coupling efficiency of the second optical path with the second MMI device; the mounting area 70 mounts the optical ATT 71 thereon. Similarly, when the optical coupling efficiency of the third optical path with the second MMI device is greater than the optical coupling efficiency of the fourth optical path with the first MMI device 40; the mounting area 80 may mount the optical ATT 81 thereon. These optical ATTs, 71 and 81, may balance the optical coupling efficiencies of the Lo light, L₁ and L₂, against the MMI devices, 40 and 50, with the optical coupling efficiencies of the Sig light, N₁ and N₂, against the MMI devices, 40 and 50, which may suppress degradation of the preciseness in the recovery of the data by the MMI devices, 40 and 50. The present embodiment sets the optical ATTs, 71 and 81, in the first optical path for the Lo light and the third optical path for the Sig light. However, at least the optical ATT 81 placed on the third optical path for the Sig light N₁ may show the function of the present invention. It is hard to assume for the Lo light that two Lo light, L₁ and L₂, spilt by the BS 12 have respective magnitude considerably different from each other, because only the BS 12 splits the Lo light. On the other hand, it is easily assumed for the Sig light N₀ that two Sig light, N₁ and N₂, have respective magnitudes considerably different from each other because of the polarization characteristic of the optical source, those of the optical components placed between the optical source and the present coherent receiver 1, and so on. In such cases, the optical ATT 81 placed in the third optical path may effectively improve the preciseness of the data recovery by the MMI devices, 40 and 50.

The present embodiment may prepare, as the optical ATT 71 for the Lo light and the optical ATT 81 for the Sig light, for instance, a plurality of ATTs of a type of light transmission each attributed to respective attenuation degrees different from each other. Selecting one of ATTs among those ATTs of the type of the light transmission depending on needed attenuation, for instance, one ATT having adequate attenuation is selected for the optical ATT 71 for the Lo light and the optical ATT 81 for the Sig light. The transmittance of the ATTs, 71 and 81, are for instance, 95 to 98%. For example, a silica glass with a reflection film or an absorption film may be applicable. The reflection film may be multi-layered film including metal films comprised of at least one of aluminum (Al) and gold (Au) and dielectric films made of, for instance, silicon nitride (SiN); while, the absorption film may be made of material containing carbon. The optical ATTs, 71 and 81, may basically have an optional outer shape; for instance, the optical ATTs, 71 and 81, may be cubic, rectangular, and/or slab shape. Also, the optical ATTs, 71 and 81, may have an optional thickness along the optical axes thereof. One example for the optical ATTs, 71 and 81, may be a cubic with one side of about 1 mm. The first and second mounting areas, 70 and 80, may be a square with one side of about 1.5 mm.

In the coherent receiver 1, a ratio of a magnitude of the first Lo light L₁ entering the first MMI device 40 against a magnitude of the second Lo light L₂ entering the second MMI device 50, and a ratio of a magnitude of the second Sig light N₂ entering the first MMI device 40 against a magnitude of the first Sig light N₁ entering the second MMI device 50 are each adjusted to be within a range of 80 to 120%.

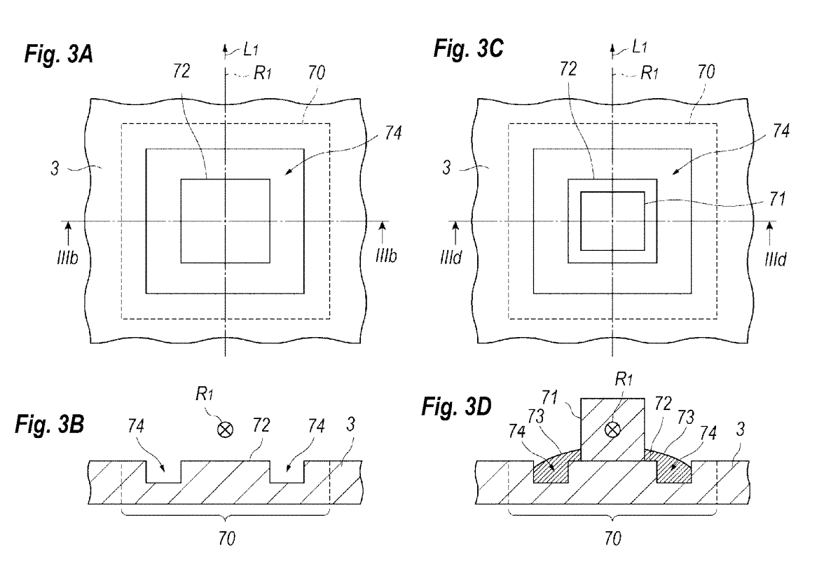

FIGS. 3A to 3D schematically illustrate the mounting area 70 according to the first embodiment of the present invention. FIG. 3A is a plan view of the mounting area 70. FIG. 3B shows a cross section taken along the line IIIb-IIIb indicated in FIG. 3A. The other mounting area 80 has arrangements same with those of the first mounting area 70; accordingly, the explanation below omits figures concerning to the second mounting area 80. As FIGS. 3A and 3B illustrate, the mounting area 70 provides a mounting surface 72 on which the optical ATT 71 is to be mounted. FIGS. 3C and 3D show the optical ATT 71 mounted on the mooting surface 72. FIG. 3C is a plan view of the mounting area 70; while, FIG. 3(d) shows a cross section taken along the ling IIId-IIId indicated in FIG. 3C. FIGS. 3A to 3D indicate the optical path R₁ of the Lo light L₁.

The mounting surface 72 provides a fixing agent 73 for fixing the optical ATT 71. FIG. 3C omits the fixing agent 73. The fixing agent 73 may be adhesive or solder. The adhesive may be an epoxy resin, while, the solder may be a low melting solder such as indium-tin (InSn), bismuth-tin (BiSn), and so on. As shown FIGS. 3A to 3D, the mounting area 70 accompanies with a structure 74 that prevents the fixing agent 73 from spreading out. The structure 74 may be, for instance, a groove surrounding the mounting surface 72. The fixing agent 73 is applied so as not to interrupt the optical path R₁. That is, the optical path R₁ is not interrupted by the mounting surface 72 and the fixing agent 73. The other mounting area 80 may also accompany with the structure for preventing the fixing agent from spreading out. The coherent receiver 1 may provide the structure 74 that prevents the fixing agent from spreading out in at least one of the mounting areas, 70 and 80.

Advantages realized in the coherent receiver 1 thus described will be explained. According to the present coherent receiver 1, the Sig light that is modulated in phases thereof may be demodulated by interfering between the Sig light and the Lo light. Also, an increased error rate due to a widened difference in the magnitudes between the Lo light and the Sig light each entering the second MMI device 50 may be effectively suppressed. That is, the magnitude of the Sig light N₁ that enters the second MMI device 50 maybe suppressed by mounting the optical ATT 81 in the mounting area 80. Accordingly, the difference in the magnitudes between the Sig light N₁ entering the second MMI device 50 and the Sig light N₂ entering the first MMI device 50 may be evened, which effectively reduces the degradation in the demodulating preciseness of the coherent receiver 1.

Also, the coherent receiver 1 provides the mounting area 70 on the path between the first BS 12 and the Lo beam input port 41 of the first MMI device 40 in order to mount the optical ATT 71 thereon. The optical ATT 71 attenuates the magnitude of the Lo light L₁ entering the first MMI device 40. The difference in the magnitudes between the Lo light L₁ entering the first MMI device 40 and the Lo light L₂ entering the second MMI device 50 may be evened. The degradation in the demodulating preciseness of the coherent receiver 1 may be further lightened.

The mounting area 70 of the coherent receiver 1 is provided on the optical path R₁ for the Lo light L₁. Mounting the optical ATT 71 on the optical path R₁, the optical coupling loss with respect to the first MMI device 40 inevitably increases; but the optical coupling loss may be improved compared with a status where the mounting area 70 is provided on the optical path R₂ for the other Lo light L₂. The other Lo light L₂ in the optical axis thereof is bent twice by the first BS 12 and the first reflector 13. The former Lo light L₁ whose optical axis is not bent is more favorable in the increase of the optical coupling loss compared with the latter Lo light L₂. Similar situation may appear in the other mounting area 80.

The coherent receiver 1 of the present embodiment provides one mounting area 70 for the Lo light and one mounting area 80 for the Sig light, which may make the coherent receiver 1 compact compared with an arrangement that provides four areas independently for the Lo light, L₁ and L₂, and for the Sig light, N₁ and N₂. The coherent receiver 1 of the embodiment may make spaces for placing the optical ATTs, 71 and 81, and areas for assembling thereof in substantially about half. In the coherent receiver 1, the magnitudes of the Lo light, L₁ and L₂, ant the magnitudes of the Sig light, N₁ and N₂, become comparable at the first and second MMI devices, 40 and 50. Moreover, during the process of assembling components, the lens systems, 14, 15, 23, and 24, may be optically aligned using the PDs, 45 and 55, that are integrated within the first and second MMI devices, 40 and 50, such that the coupling efficiencies with respect to the PDs, 45 and 55, become respective maxima. When the coupling efficiencies detected by the PDs, 45 and 55, are unable to be comparable, the optical ATTs, 71 and 81 are set on the respective optical paths so as to compensate the discrepancy of the coupling efficiencies of the two Lo light, L₁ and L₂, and for the two Sig light, N₁ and N₂, with respect to the MMI devices, 40 and 50.

The coherent receiver 1 provides the mounting surfaces, 72 and 82, in the mounting areas, 70 and 80, where the mounting surfaces, 72 and 82, accompany with adhesive or solder. The optical ATTs, 71 and 81, may be easily and securely fixed on the mounting surfaces, 72 and 82, by the adhesive or solder. Because the adhesive or solder creeps up the sides of the optical ATTs, 71 and 81, the fixation of the optical ATTs, 71 and 81, may become further tight.

At least one of the mounting areas, 70 and 80, may further provide the structure 84 that prevents the adhesive or solder from spreading out. According to the present coherent receiver 1, when the optical ATTs, 71 and 81, are mounted on the mounting areas, 70 and 80, the adhesive or solder may be prevented from spreading outward from the mounting areas, 70 and 80. The structure 83 may be utilized as identifiers for aligning the optical ATTs, 71 and 81, on the mounting areas, 70 and 80.

First Modification

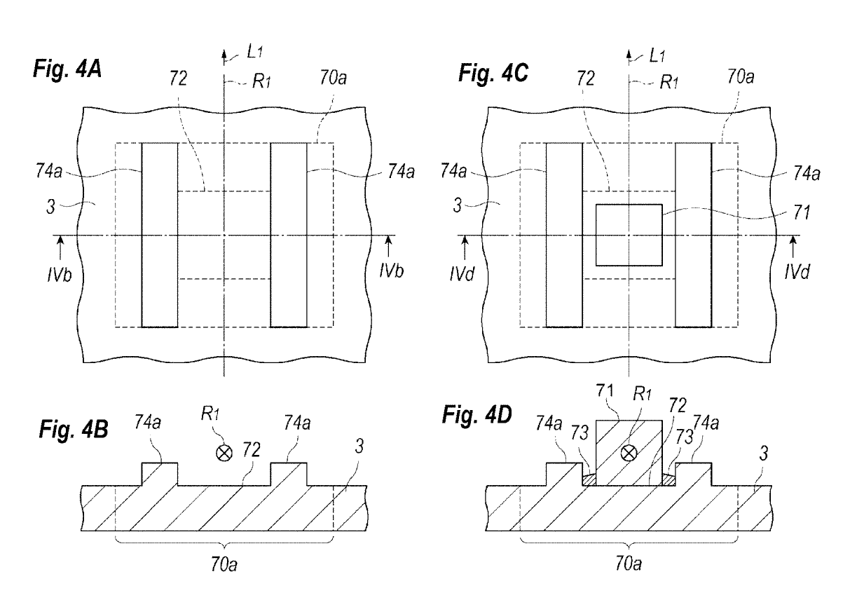

FIGS. 4A to 4D schematically illustrate the mounting area 70a according to the first modification of the present invention. FIG. 4A is a plan view of the mounting area 70a. FIG. 4B shows a cross section taken along the line IVb-IVb indicated in FIG. 4A. As shown in FIGS. 4A and 4B, the mounting area 70a provides the mounting surface 72 on which the optical ATT 71 is mounted. Similarly, the other mounting area 80a may provide the mounting surface 82 for mounting the optical ATT 81. FIGS. 4C and 4D show the optical attenuator 71 mounted on the mounting surface 72. FIG. 4C is a plan view of the mounting area 70a, while, FIG. 4D shows a cross section taken along the line IVd-IVd indicated in FIG. 4C. FIGS. 4A to 4D show the optical path R₁ for the Lo light L₁. The mounting area 72 according to the first modification accompanies the fixing agent 73 for fixing the optical ATT 71. As shown in FIG. 4D, the optical ATT 71 is fixed on the mounting surface 72 by the fixing agent 73, where FIG. 4C omits the fixing agent 73. The mounting area 70a accompanies a protruding mound 74a as a mechanism for preventing the fixing agent from spreading out. The mound 74a may be two ribs extending along the optical path R₁. Two ribs do not interfere with the optical path R₁ for the Lo light L₁. The fixing agent 73 is applied so as not to interfere with the optical path R₁ for the Lo light L₁. The mounting area 70a may be formed by shaping the mounting surface 72 so as to accompany with the protruding mound 74a. Or, a structure 70a of a rectangular slab shape with an opening in a center thereof may be mounted on the mounting surface 72 to form the mounting area 70. The coherent receiver 1 may provide the structure 74a for preventing the fixing agent 73 from spreading out in at least one of the mounting areas, 70a and 80a. Thus, the adhesive or solder may be prevented from spreading out from the mounting area 70a where the optical ATTs, 71 and 81, are mounted on the respective mounting areas, 70a and 80a.

Second Modification

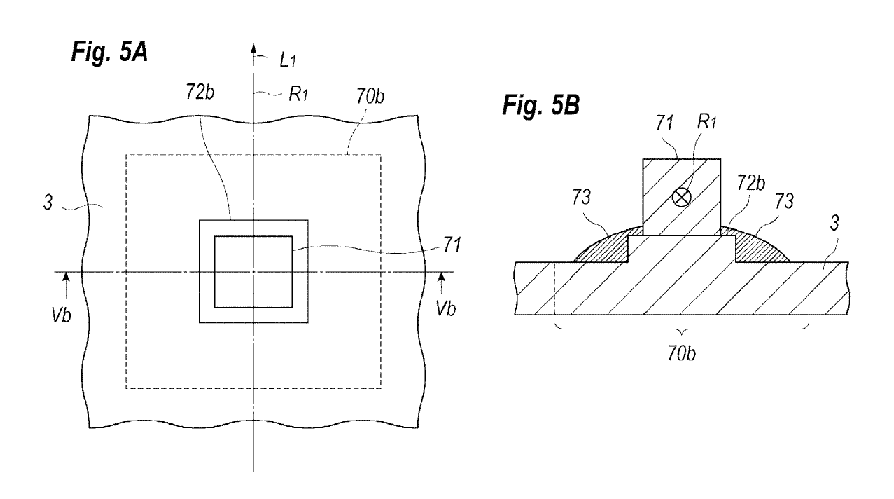

FIGS. 5A and 5B schematically illustrate the second modification. FIG. 5A is a top plan view of the mounting area 70b according to the second modification, where FIG. 5A illustrates the optical path R₁ for the Lo light L₁, while, FIG. 5B shows a cross section taken along the line Vb-Vb indicated in FIG. 5A.

As FIGS. 5A and 5B illustrate, the mounting area 70b provides the mounting surface 72b. The mounting surface 72b may be, for instance, a protruding terrace. The optical ATT 71 is mounted on the mounting surface 72b. The coherent receiver 1 may provide the terrace in at least one of the mounting surface 72b of the second modification and the mounting surface for the Sig light N₁. The mounting surface 72b of the second modification accompanies the fixing agent 73. As shown in FIG. 5B, the optical ATT 71 in the second modification is fixed on the mounting surface 72b by the fixing agent 73, where FIG. 5A omits the fixing agent 73. The fixing agent 73 is applied so as not to interrupt the optical path R₁ for the Lo light L₁. The optical path R₁ is not interrupted by the fixing agent 73 on the mounting surface 72b.

At least one of the mounting surface 72 and the other mounting surface may provide the terrace like the present modification. Thus, the optical ATTs, 71 and 81, may be mounted on the mounting surfaces, 72 and 82, by aligning levels of the Lo light and the Sig light.

Third Modification

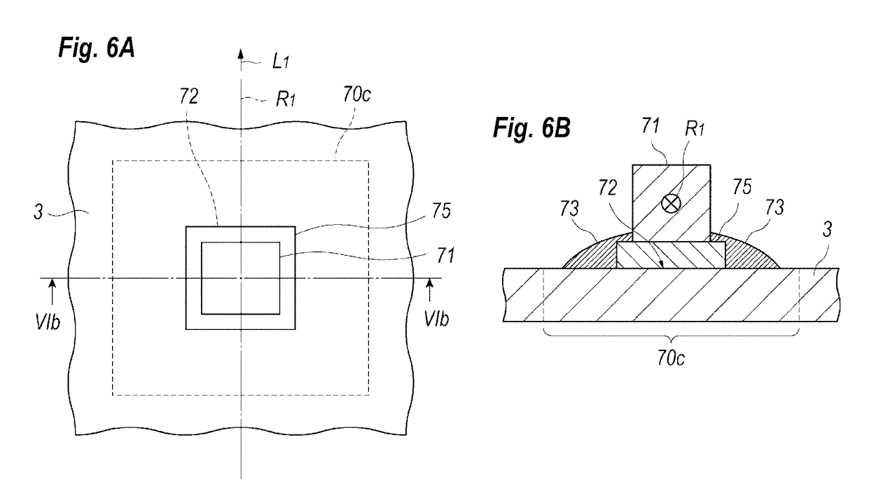

FIGS. 6A and 6B schematically show the third modification of the present invention. FIG. 6A is a plan view of the mounting area 70c, while, FIG. 6B shows a cross section taken along the line VIb-VIb indicated in FIG. 6A. FIG. 6A also indicates the optical path R₁ for the Lo light L₁.

As FIGS. 6A and 6B illustrate, the mounting area 70c provides a mounting platform 75 on the mounting surface 72. The mounting platform 75 may be made of, for instance, alumina (Al₂O₃). The optical ATT 71 is mounted on the mounting platform 75. Similarly, the other mounting area may accompany with a mounting platform on the mounting surface for mounting the optical ATT 81 thereon. The coherent receiver 1 may provide the mounting platform 75 in at lease on the mounting area 70c or the other mounting area. The mounting surface 72 of the third modification provides the fixing agent 73 for fixing the optical ATT 71. The optical ATT 71 is fixed onto the mounting surface 72 by the fixing agent 73. FIG. 6A omits the fixing agent 6. The fixing agent 73 may be applied so as not to interrupt the optical path R₁ for the Lo light L₁. The optical path R₁ is not interrupted by the mounting platform 75 and the fixing agent 73.

At least one of the mounting areas may provide the mounting platform 75 like the present modification. Thus, the optical ATTs, 71 and 81, may be mounted on the mounting surface 72 and the second mounting surface as aligning the levels thereof with the height of the optical paths of the Lo light and the Sig light.

Fourth Modification

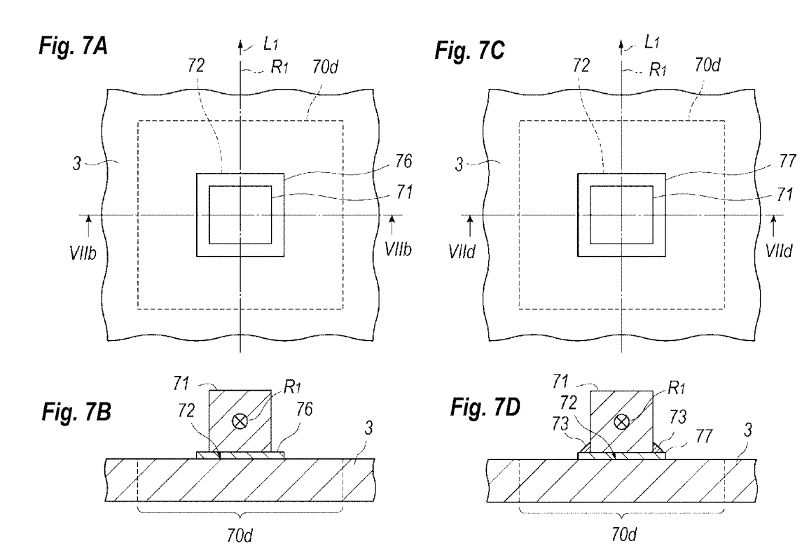

FIGS. 7A and 7C schematically illustrate the mounting area according to the fourth modification. FIGS. 7A and 7C are plan views of the mounting area 70d, while FIG. 7B shows a cross section taken along the line VIIb-VIIb indicated in FIG. 7A. FIG. 7D also shows a cross section taken along the ling VIId-VIId indicated in FIG. 7C.

As FIGS. 7A and 7B illustrate, the mounting area 70d provides brazing material 76 on the mounting surface 72. The optical ATT 71 is mounted on the brazing material 76. The brazing material 76 may be made of material same with the fixing agent 73. The brazing material 76, which may be applied by, for instance, a screen printing and has a melting temperature lower than that of a compound of SnAgCu for fixing the other optical components such as first BS 12. The optical path R₁ for the Lo light L₁ is not also interrupted with the brazing material 76 of the fourth modification.

The fourth modification, as FIGS. 7C and 7D illustrate, may further provide a metal film 77 on the mounting surface 72. The metal film 77 may be a plated gold (Au) and a plated nickel (N₁). FIG. 7D shows the optical ATT 71 fixed on the metal film 77 formed on the mounting surface 72 by the fixing agent 73, where FIG. 7C omits the fixing agent 73. As FIG. 7D shows, the fixing agent 73 is applied so as not to interrupt the optical axis R₁ for the Lo light L₁. The mounting area for the Sig light N₁ may also provide the brazing material 76 or the metal film 77.

The coherent receiver 1 may provide the brazing material 76 and the metal film 77 on at least one of the mounting surface 72 and the other mounting surface for the Sig light N₁. Thus, the optical ATTs, 71 and 81, may be easily fixed onto the mounting surface 72 and the other mounting surface. The metal film 77 may enhance wettability of the brazing material, which makes the brazing easy. When the mounting surface 72 is oxidized, which degrades the wettability of the brazing material, the metal film 77 becomes particularly effective for an oxidized mounting surface 72.

Also, the brazing material 76 applied to the mounting surface 72 preferably has a melting temperature lower than that of other brazing materials for fixing the other optical components such as the first BS 12. Under such a condition, when the brazing material 76 on the mounting surface 72 is melted, the other brazing material that fixes the other optical components like the first BS 12 is not melted; accordingly, positional deviations of those optical components may be effectively prevented. When the other optical components like the first BS 12 is mounted after the mount of the optical ATTs, 71 and 81, the brazing material on the mounting surfaces, 72 and 82, possibly melt. However, the mounting surfaces, 72 and 82, are oxidized and enhance repellent of the brazing material, the mounting surfaces, 72 and 82, may effectively suppress the overflow of the brazing material.

Fifth Modification

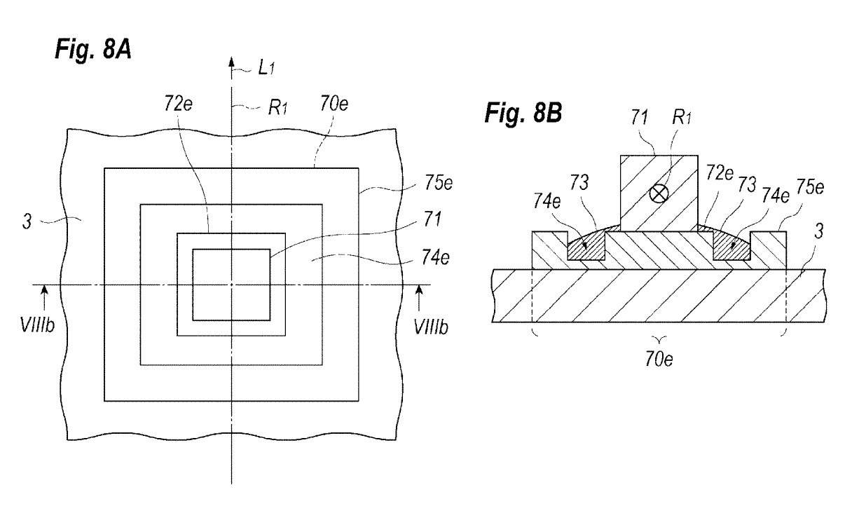

FIGS. 8A and 8B schematically illustrate the fifth modification. FIG. 8A is a plan view of the mounting area 70e, FIG. 8B shows a cross section taken along the line VIIIb-VIIIb indicated in FIG. 8A. In the fifth modification, the mounting area 70 provides a terrace 75e that may provide a structure with a depressed cross section for preventing the fixing agent from spreading out. The structure 74e with the depressed cross section for preventing the spread may be a groove surrounding the mounting surface 72. The terrace 75e may be fixed on the mounting area 70e by, for instance, solder of AuSn eutectic alloy. The fixing agent 73 is applied so as not to interrupt the optical path R₁ for the Lo light L₁. The optical path R₁ for the Lo light L₁ is also not interrupted by the terrace 75e and the fixing agent 73 of the fifth embodiment.

The terrace 75e may provide, instead of the depressed groove 74e, a protruding mound shown in FIG. 4D. The mound includes two ribs extending along the optical path R₁. Two ribs are formed so as not to interrupt the optical path R₁ for the Lo light L₁. The coherent receiver 1 provides the terrace 75 in at least one of the mounting area 70e and the other mounding area for the Sig light N₁, where the terrace 75e may provide the mound or the groove for preventing the fixing agent 73 from spreading out. Thus, the adhesive or the brazing material is prevented from spreading out in a periphery of the terrace 75e when the optical ATTs, 71 and 81, are mounted.

Sixth Modification

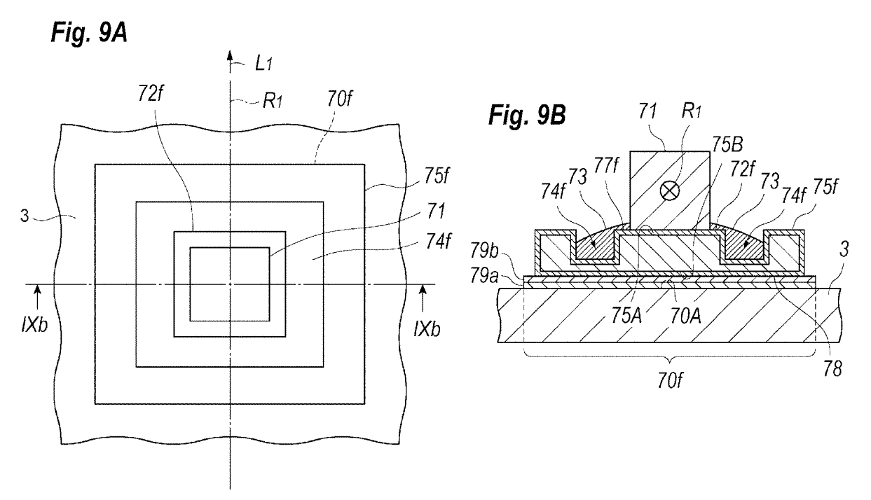

FIGS. 9A and 9B schematically illustrate the sixth modification. FIG. 9A is a plan view of the mounting area 70f. FIG. 9B shows a cross section taken along the line IXb-IXb indicated in FIG. 9A.

The terrace 75f provides a metal film 78 in the bottom thereof, and another metal film 77f in the top 75A. Moreover, the terrace 75f is mounted in the mounting area 70f by, forming the third meal film 79a on the top surface 70A of the carrier 3 and interposing an adhesive material 79b between the bottom 75B of the terrace 75f and the top surface 70A of the mounting area 70f. The adhesive material 79b may be, for instance, adhesive and/or brazing material. The terrace 75f provides a groove 74f surrounding the mounting surface 72f. The fixing agent 73 is applied so as not to interrupt the optical path R₁ of the Lo light L₁. The optical path R₁ of the Lo light L₁ is not interrupted by the terrace 75f and the fixing agent 73 of the sixth modification. The other mounting area for the Sig light N₁ may provide the terrace 75f. The coherent receiver 1 may provide the terrace 75 that has the bottom 75B with the second metal film 78 in at least one of the two mounting areas. The terrace 75f like the present modification may provide the bottom 75B with the second metal film 78. Thus, when the terrace 75f is mounted on the mounting area 70 for the second mounting area, the wettability increases and the brazing may be in facilitated.

### Second Embodiment

A process of assembling the coherent receiver 1 configured with the arrangement thus described above according to the present invention and will be described.

First, the carrier 3 mounts and fixes the base 4 thereto in an outside of the housing 2. The carrier 3 may be made of, for instance, coper tungsten (CuW) and a rectangular slab shape. The base 4 may be made of, for instance, alumina (Al₂O₃) and also a rectangular slab shape. Eutectic solder such as gold tin (AuSn) may fix the base 4 with the carrier 3. The carrier 3 provides a groove on a surface thereof where the grooves distinguish an area for mounting the base 4 from another area for mounting the MMI devices, 40 and 50. Aligning a rear end of the base 4 with a front edge of the groove only by visual inspection, the carrier 4 may determine a position thereof on the base 3 along a longitudinal direction of the housing 2. In an alternative, the base 4 in the front edge thereof may be aligned with the front edge of the carrier 3.

When the carrier 3 is to be installed within the housing 2, it will be preferable to hold the carrier 3 in narrowed portions formed in the respective sides thereof because the carrier 3 in a width thereof is substantially equal to an inner width of the housing 2. Moreover, a lateral alignment of the base 4 against the housing 2 may be carried out using the narrowed portion of the carrier 3. That is, because the carrier 3 in center portions of the respective sides has the narrowed portions, the base 4 in a lateral position thereof may be aligned with the narrowed portions of the carrier 3.

Then, the process mounts the MMI device 40 on a MMI carrier, which is not illustrated in the figure, and fixes thereto. Similarly, the MMI device 50 is mounted on another MMI carrier, which is also not illustrated in the figure, and fixed thereto. The MMI carries may be a rectangular block and made of ceramics such as alumina. The fixation of the MMI devices, 40 and 50, to the MMI carriers may be carried out by the eutectic solder of, for instance, gold tin (AuSn). A conventional technique for mounting a semiconductor device on an insulating substrate may be applied to the fixation. Thereafter, the process fixes the MMI carriers mounting the MMI devices, 40 and 50, in respective areas on the carrier 3 behind the base 4. Because the carrier 3 prepares grooves that surround the areas where the MMI carriers are to be fixed thereto, the MMI carriers may be placed on the respective areas only through the visual inspection.

The MMI carriers in surfaces thereof prepare grooves that distinguish front sides from rear sides. The front sides of the MMI carriers correspond to portions in the MMI devices, 40 and 50, where waveguides, 44 and 54, are integrated therein. On the other hand, the rear sides of the MMI carriers correspond to portions in the MMI devices where PDs, 45 and 55, are integrated. The MMI devices, 40 and 50, in back metals thereof are separated between front areas and rear areas. Accordingly, the PDs, 45 and 55, integrated within the MMI devices, 40 and 50, may reduce leak currents thereof.

Concurrently with the fixation of the MMI devices, 40 and 50, on the MMI carriers, the process mounts die-capacitors (parallel plate capacitors) onto circuit boards, 46 and 56. The circuit boards, 46 and 56, may be made of, for instance, aluminum nitride (AlN). The mount of the die capacitors may use, for instance, gold tin (AuSn) pellet, or conventional soldering. Thereafter, one of circuit boards 46 that mounts the die capacitors thereon is fixed on the carrier 3 so as to surround the MMI device 40, and another of the circuit boards 56 is also fixed on the carrier 3 so as to surround the MMI device 50. The fixation of the circuit boards, 46 and 56, may be carried out by, for instance, eutectic solder of AuSn. Then, the process installs the carrier 3 within the housing 2.

The carrier 3 is installed on the bottom 2E of the housing 2. Specifically, aligning the carrier 3 with respect to the housing 2 by abutting the front edge of the carrier 3 against an inside of the front wall that constitutes one side 2A of the housing 2, and retreating the carrier 3 from that side by a preset amount, the carrier 3 is placed on the bottom 2E of the housing 2. The respective insides of the side wall, as shown in FIG. 2, provide steps dividing an upper part made of metal from a lower part forming feedthroughs 61 and made of ceramics in order to electrically isolate the terminals 3. The lower part in an inner dimension thereof between the walls is substantially equal to the width of the carrier 3, but the upper part in the inner width thereof is wider than the width of the carrier 3. Accordingly, the carrier 3 may be abut against the inside of the upper part of the side wall, which may align the carrier 3 and the components mounted on the carrier with respect to the housing 2 within accuracy of ±0.5°. Solder may fix the carrier 3 onto the bottom 2E.

The process described above also mounts the VOA carrier 30 onto the bottom 2E of the housing 2 concurrently with the mount of the carrier 3. Abutting the front end of the VOA carrier 30 against the inside of the one side 2A of the housing 2 to align the VOA carrier 30 with respect to the housing 2, then retreating the VOA carrier 30 from the side 2A by a preset amount, the process may place the VOA carrier 30 onto the bottom 2E of the housing 2. This procedure may set the front end of the carrier 3 in parallel to the rear end of the VOA carrier 30. Solder may fix the VOA carrier 30 to the bottom 2E.

After the fixation of the carrier 3 onto the bottom 2E, the process mounts the integraed circuits, 43 and 53, refer to FIGS. 1 and 2, on the circuit boards, 46 and 56. The assembly of the integeraetd circuits, 43 and 53, may be carried out by a conventional technique, for instance, using electrically conductive paste such as, what is called silver paste. After the mounting of the integrated circuits, 43 and 53, heat treatment around 180° C. of the whole housing 2 may vaporize solvents contained in the conductive paste. Then, bonding wires electrically connect pads provided on the top surface of the integrated circuits, 43 and 53, with the terminals 65 prepared in the rear of the housing, refer to FIGS. 1 and 2. The wiring may enable the active alignment of optical components carried out in subsequent processes; that is, practically entering test beams into the MMI devices, 40 and 50, and disposing the optical components at respective positions where outputs of the PDs, 45 and 55, built within the MMI devices, 40 and 50, become respective maxima.

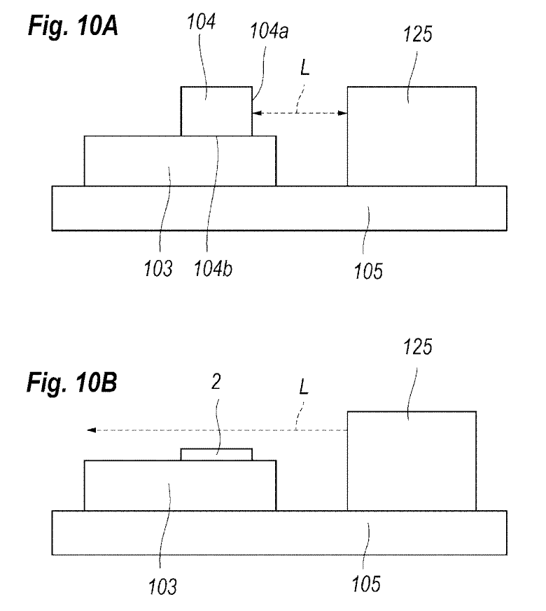

Next, optical components will be installed within the housing 2. First, a Lo light for the optical alignment is prepared. As FIG. 10A indicates, the process prepares a reference reflector 104 having a reflecting surface 104a and a bottom surface 104b perpendicular to each other. The reflecting surface 104a simulates the one side wall 2A of the housing 2, while, the bottom surface 104b simulates the bottom 2E of the housing 2. The reference reflector 104 is mounted on a stage 103 that is fixed on the base 105 of the alignment apparatus. The bottom surface 104b is closely in contact with the stage 103.

The autocollimator 125 in an optical axis thereof is aligned with the optical axis of the reference reflector 104. Specifically, visible laser light L output from the autocollimator 125 irradiates the reflecting surface 104a of the reference reflector 104. Then, the autocollimator 125 detects the magnitude of the reflected visible laser light L. When the reflected visible laser light L coincides with the visible laser light L before the reflection, the detected magnitude becomes a maximum. According to the procedures above, the normal of the reflecting surface 104a, that is, the optical axis of the reference reflector 104 coincides with the optical axis of the autocollimator 125. Then, removing the reference reflector 104 from the stage 103 and places the housing 2 that installs the MMI devices, 40 and 50, the circuit boards, 46 and 56, and the VOA carrier 30 thereon (FIG. 10B). The bottom of the housing 2 is closely in contact with the stage 103. Because the optical axis of the autocollimator 125 passes above the housing 2, the visible laser light L does not enter within the housing 2.

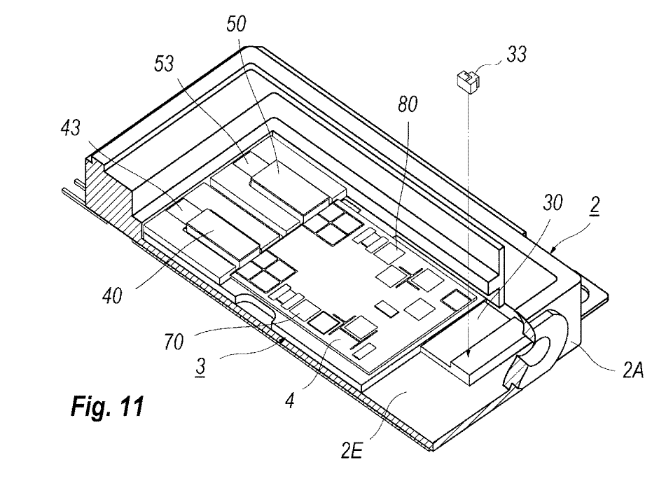

Then, as shown in FIG. 11, the process mounts the monitor PD 33 on the VOA carrier 30, and the PBS 21, the skew adjusting devices, 16 and 26, the λ/2 plate 25, the polarizer 11, and the BS 12 are placed on the respective positons. These optical components are unnecessary to be optically aligned and only optical incident surfaces in directions thereof are aligned then fixed thereto. Specifically, the process adjusts the angles of those optical components using the optical axis of the autocollimator 125 that are aligned in advance thereto. Assuming one of surfaces of those optical components as the reflecting surfaces for the visible laser light L coming from the autocollimator 125, the angles of those optical components are aligned so as for the visible laser light L after the reflection to coincide with the visible laser light L before the reflection. The procedures above may be carried out on the optical axis of the autocollimator 125 that is in the space above the housing 2. Moving the optical components on adhesive resin prepared on the positions for the respective optical components as maintaining the angles of the optical components, or rotating by a preset angle if necessary, the optical components are fixed thereto by hardening the adhesive resin.

Because the PBS 21, the skew adjusting devices, 16 and 26, and the polarizer 11 in the incident surfaces thereof face the front wall 2A, those components are preferably installed by maintaining the directions thereof after the incident surfaces thereof are aligned with the optical axis of the autocollimator 126. While, the λ/2 plate 25 and the monitor PD 33 in the incident surfaces thereof face the side of the housing 2; those components are preferable to be installed after aligning the normal of the incident surfaces thereof with the optical axis of the autocollimator 125 and rotating by 90° around the normal of the bottom 2E. The monitor PD 33 is further carried out the electrical connection with the preset terminal 61 through the bonding wire. For the BS 12, when the BS 12 is installed within the housing 2, the incident surface thereof faces the side but the emitting surface thereof faces the rear. Accordingly, the BS 12 is preferably installed as maintaining the angle thereof after aligning the normal of the outgoing surface, or the surface opposite thereto, with the optical axis of the autocollimator 125.

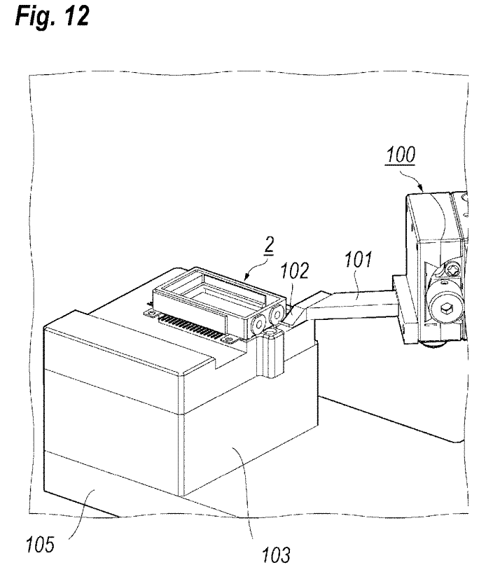

Thereafter, other optical components are installed, where the optical components are the Sig light lens 27, the first and second reflectors, 13 and 22, and the lens systems, 14, 15, 23, and 24, that have lessor coupling tolerances against the MMI devices, 40 and 50; accordingly they are necessary to be aligned. In advance to the installation, as shown in FIG. 12, dummy connectors, 123a and 123b, are disposed onto the front wall 2A of the housing 2. The dummy connectors, 123a and 123b, simulate the Sig light input port 6 and the Lo light input port 5, respectively, and provide test beams for aligning the other optical components described above. Next, the procedures to prepare the test beam will be described in detail.

FIG. 12 is a perspective view of a portion of manipulator 100 that supports the dummy connector 123a. The manipulator 100 includes an arm 101 and a head 102 held in an end of the arm 101 whose positions and angles are optionally adjustable; that is, positions along three axes of X, Y, and Z perpendicular to each other and angles around two axes perpendicular to the optical axis of the dummy connector 123a are adjustable. The dummy connector 123a, which is supported on the head 102, is positioned where the Sig light input port 6 is to be attached. The other dummy port 123b is also positioned where the Lo light input port 5 is to be attached as being supported by another manipulator 100 similar to the manipulator 123a.

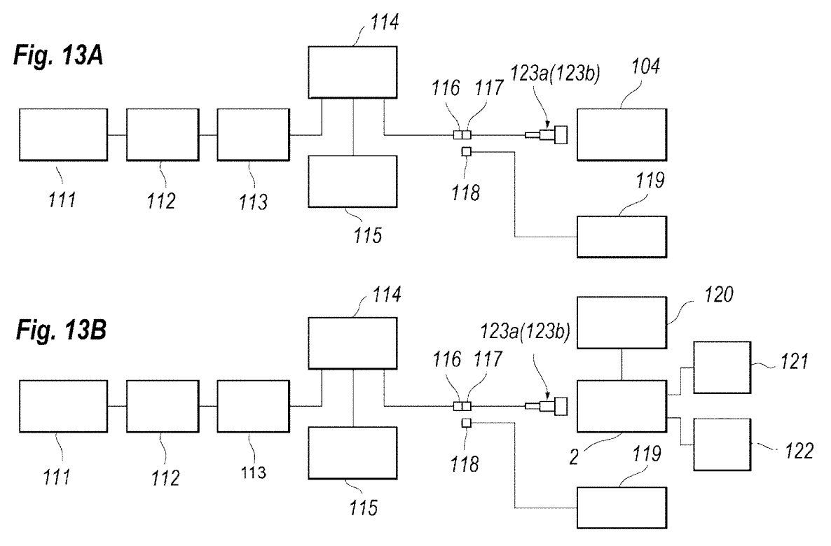

FIG. 13A shows a functional block diagram of a system for generating the test beam. The system generates the test beam, which is a CW beam, by supplying biases from the bias supply 111 to the optical source 112, which may be, for instance, a semiconductor laser diode. The test beam thus generated is provided to the polarization controller 113 that adjusts the polarization of the test beam. Thus, the test beam may provide two polarization components each simulating those of the Sig light. Thereafter, the test beams reaches the connector 116 through the optical coupler 114. The connector 116 is selectively coupled with one of the connectors, 117 and 118. The former connector 117 is coupled with the dummy connector 123a, while, the latter connector 118 is coupled with a power meter 119. The optical coupler 114 is connected also with another power meter 115. The system shown in FIG. 13A provides two power meters, 115 and 119, but the system may provide only one power meter selectively applied to the power meters, 115 and 119. Also, the dummy connector 123a may be used for the other dummy connector 123b.

First, the optical connector 116 is connected with the optical connector 118. The power meter 119 may detect the magnitude of the test beam provided from the optical source 112, and sets the magnitude of the test beam entering the housing 2 in a preset value by adjusting the biases. Then, the system removes the housing 2 from the stage again and places the reference reflector 104 thereon. Connecting the optical connector 116 with the optical connector 117 and the dummy connectors, 123a and 123b, face the reflecting surface 104a of the reference reflector 104. Outputting the test beam from the optical source 112, the test beam is output from the dummy connectors, 123a and 123b, and reflected at the reflecting surface 104a and back to the dummy connectors, 123a and 123b. The power meter 115 may detect the reflected test beam through the optical coupler 114. Adjusting the dummy connectors, 123a and 123b, so as to maximize the magnitude of the reflected test beam; the optical axes of the dummy connectors, 123a and 123b, may be aligned with the optical axis of the reference reflector 104. Then, the reference reflector 104 is removed from the stage 103, and the system sets the housing 2 thereon, as shown in FIG. 13B.

Then, the system adjusts the polarization of the test beam entering the housing 2 through the dummy connector 123a, which is step S1. In order to carry out the adjustment, a test tool that provides two monitor PDs and a PBS is set behind the dummy connector 123a, for instance, on a position where the VOA 31 is to be placed. The test tool may have two monitor PDs each attached to two output surfaces of the PBS, respectively. Or, the test tool may be mounted on a substrate as optically coupling the two monitor PDs with the respective output surfaces of the PBS. Providing the test beam within the housing 2 through the dummy connector 123a, and detecting magnitudes of the respective polarization components each output from the PBS by the two monitor PDs, the polarization controller 113 adjusts the polarization direction of the test beam such that the two polarization components become substantially even. This step may prepare a dummy module that installs the polarization beam splitter and two monitor PDs on the stage 103 instead of the housing 2, and adjust the polarization direction.

In the adjustment of the polarization direction, the outputs of the two monitor PDs may be output through the terminals 65 of the housing 2. Also, when the test tool prepares terminals for extracting the outputs of the two monitor PDs, the adjustment of the polarization direction may be carried out in advance to the placement of the housing 2 on the stage 103.

This step further carries out the alignment of the dummy connectors, 123a and 123b. First, the PD integrated within the first MMI device 40 detects the magnitude of the test beam entering the housing 2 through the dummy connector 123a. Sliding the dummy connector 123a on the front wall 2A along directions so as to increase the magnitude of the test beam, the dummy connector 123a may be aligned in the plane perpendicular to the optical axis thereof. Similarly, detecting the magnitude of the test beam entering the housing 2 through the dummy connector 123b by the PD integrated within the second MMI device 50 and sliding the dummy connector 213b on the front wall 2A along directions so as to increase the magnitude, the dummy connector 123b may be aligned in the plane perpendicular to the optical axis thereof. The test beam has a field diameter of about 300 μm, while, the input ports of the MMI devices, 40 and 50, have dimensions of several micron-meters in a width and 1 μm or smaller in a thickness. Accordingly, although the magnitude of the test beam entering the MMI devices, 40 and 50, become faint, but substantial magnitude are available for determining the optical axes of the test beam.

The positions of the dummy connectors, 123a and 123b, along the optical axes may be determined by abutting the dummy connectors, 123a and 132b, against the front wall 2A of the housing 2.

Next, the process disposes the other optical components, which are necessary to be aligned, between the dummy connector, 123a or 123b, and the MMI devices, 40 and 50, and referring to the detected magnitudes output from the monitor PDs within the MMI devices, 40 and 50, or the monitor PD 33, the other optical components are optically aligned. Thereafter, the other optical components are fixed within the housing 2. The turn of the optical alignment for those optical components is not restricted to that described below. The turn may be optional.

This step, as FIG. 13B illustrates, the VOA bias source 120 and the voltage monitors, 121 and 122, are connected to the housing 2. The VOA bias source 120 supplies the bias to the VOA 31 when the VOA 31 is mounted on the VOA carrier 30. The voltage monitors, 121 and 122, may monitor voltage signals on the circuit boards, 46 and 56.

The BS 32 is first aligned and fixed, refer to FIGS. 1 and 2. Specifically, the BS 32, whose front surface is set as a reflecting surface, the visible laser light L coming from the autocollimator 125 and passing the space above the housing 2 may align the angle of the BS 32, namely, the optical axis of thereof. Maintaining the angle of the BS 32, the BS 32 is moved onto the VOA carrier 30. Then, sliding the BS 12 on the VOA carrier 30 along the optical axis of the Sig light, and determining the position of the BS 12 where the output from the monitor PD 33 becomes a maximum, the BS 12 is fixed on the VOA carrier 30 by adhesive.

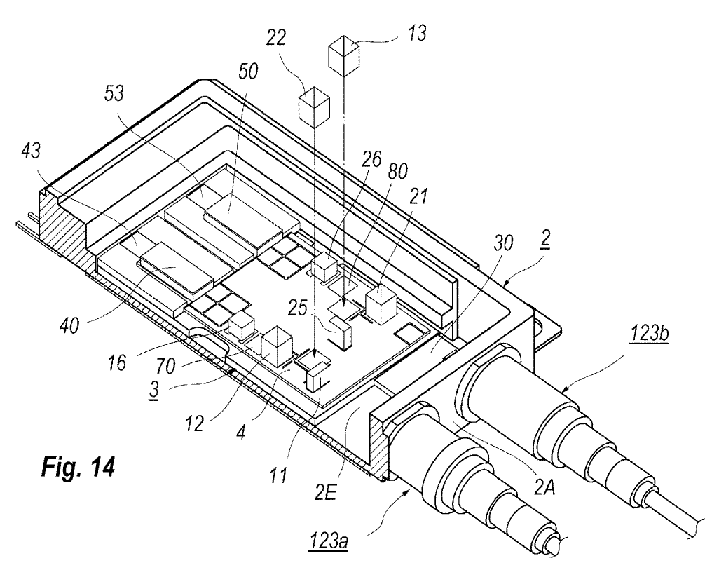

Next, the process aligns and fixes the first and second reflectors, 13 and 22, as shown in FIG. 14. Specifically, setting the front surfaces of the reflectors, 13 and 22, as the reflecting surfaces, the visible laser light from the autocollimator 125 passing the space above the housing 2 may adjust the directions of the reflectors, 13 and 22, namely optical axes thereof. Maintaining the angles of the reflectors, 13 and 22, the built-in PDs in the MMI devices, 40 and 50, detect the light reflected by the reflectors, 13 and 22. Slightly sliding the reflectors, 13 and 22, along the direction perpendicular to the optical axes of the two input ports, 5 and 6; the system determines the positions of the reflectors, 13 and 22, at which the outputs of the built-in PDs become maxima. Note that, the angles thereof determined through the visible laser light coming from the autocollimator 125 are maintained during the whole alignment of the reflectors, 13 and 22. Because the MMI devices, 40 and 50, in the angles with respect to the housing 2, and the optical axes of the light input ports, 5 and 6, are already determined; the adjustment of the angles of the reflectors, 12 and 21, which vary the optical axes by 90°, deforms the alignment of those components.

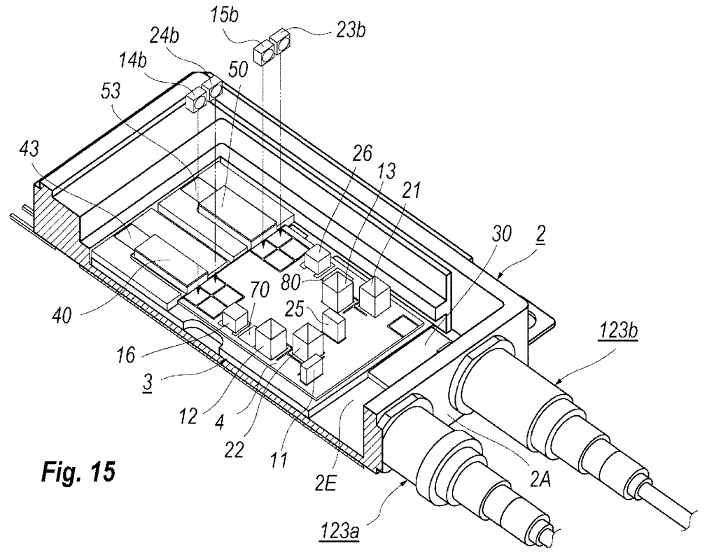

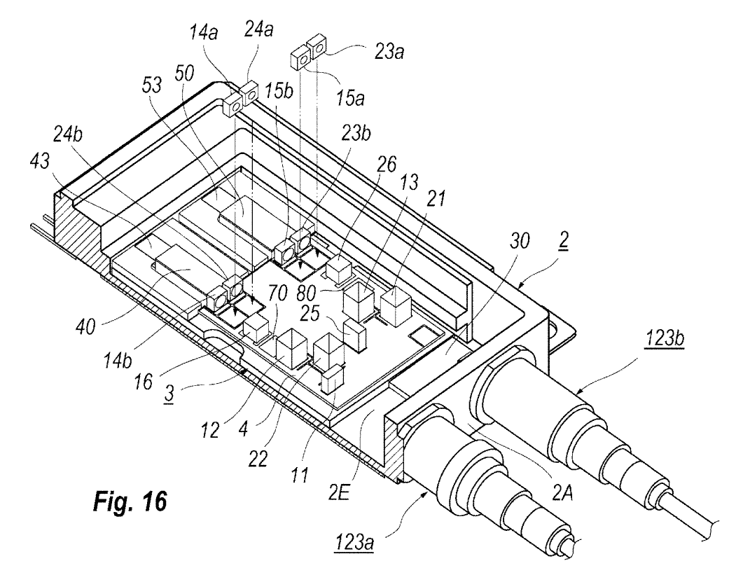

Thereafter, the process aligns and fixes the four lens systems. Specifically, as FIG. 15 shows, the process aligns respective first lenses, 14b, 15b, 23b, and 24b, positioned closer to the MMI devices, 40 and 50. Disposing these first lenses, 14b, 15b, 23b, and 24b, in respective designed positions, entering the test beams through the dummy connectors, 123a and 123b, and passing these lenses, 14b, 15b, 23b, and 24b; the test beams entering the MMI devices, 40 and 50, may be detected by the built-in PDs, 44 and 55. Slightly deviating the positions and angles of these lenses, 14b, 15b, 23b, and 24b, the positions and the angles are determined at which the magnitudes sensed by the built-in PDs become maxima. After the determination of the positions and the angles, ultraviolet curable resin may fixe the lenses, 14b, 15b, 23b, and 24b. Subsequently, as FIG. 16 indicates, the process carries out the alignment and the fixation of the second lenses, 14a, 15a, 23a, and 24a. The alignment and the fixation of these lenses are substantially similar to those performed for the first lenses, 14b, 15b, 23b, and 24b.

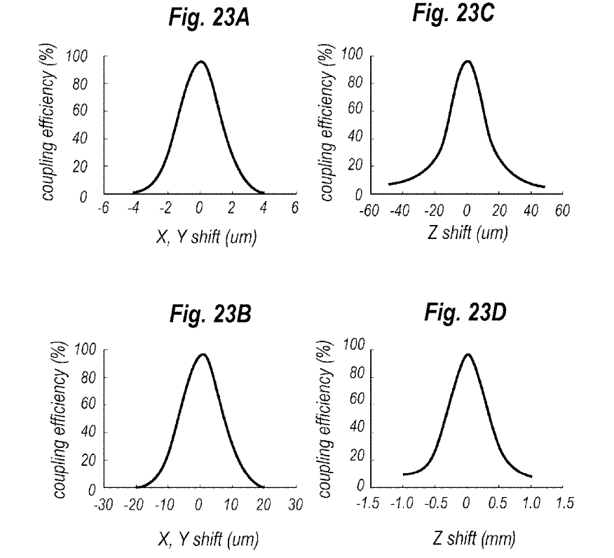

A reason why the lens systems, 14, 15, 23, and 24, provide two lenses, where they are concentrating lenses, disposed along the optical axis will be described. FIG. 23 shows variations in the coupling efficiency, the coupling efficiencies with respect to the beam input ports of the MMI devices, 40 and 50, in the present embodiment, against deviations of the position of the lens from the designed position when two lenses are arranged along the optical axis. FIGS. 23A and 23B shows the tolerances against the deviation of the lens disposed in the side of the object to be coupled, namely, a lens disposed relatively closer to the object to be coupled, where FIG. 23A corresponds to the deviation perpendicular to the optical axis, while FIG. 23B corresponds to the deviation parallel to the optical axis. Also, FIGS. 23C and 23D show variations of the coupling efficiency against deviations of the lens disposed in the side opposite to the object to be coupled, namely, a lens disposed relatively apart from the object to be coupled, where FIG. 23C corresponds to a deviation perpendicular to the optical axis, while, FIG. 23D corresponds to a deviation parallel to the optical axis. FIGS. 23C and 23D assume that a lens disposed in the side of the object to be coupled is set in the designed position.

The deviation along directions (X, Y) perpendicular to the optical axis is first investigated. As shown in FIG. 23A, for the lens disposed in the side of the object to be coupled, merely a few micron meters deviation degrades the coupling efficiency, that is, merely one micron meter deviation results in the degradation of the coupling efficiency of 30%. On the other hand, as FIG. 23C indicates, the lens disposed in the side opposite to the object to be coupled, a few micron meters deviation substantially causes no degradation in the coupling efficiency, and substantial degradation requires deviation of several scores of micron meters. Also, investigating the deviation along the optical axis, as FIG. 23B indicates, the lens set in the side of the object to be coupled varies the coupling efficiency even in deviation of several scores of micron meters; while, as FIG. 23D indicates, the lens set opposite to the object to be coupled causes substantially no degradation in the coupling efficiency even when deviation of several scores of micron meters.

The lenses in the respective lens systems, 14, 15, 23, and 24, are fixed to the base 4 by resin, for instance, ultraviolet curable resin. Because resin inevitably shrinks during the curing almost several micron meters, the positions of the lenses possibly deviate by several micron meters during the curing of the resin. Moreover, as descried above, for the lenses disposed in the side of the object to be coupled, merely a few micron meters deviation degrades the coupling efficiency.

On the other hand, the lenses disposed opposite to the object to be coupled, even a few micron meters deviation causes substantially no degradation in the coupling efficiency, which means that a remarkable positional tolerance may be secured for the lenses disposed opposite to the object to be coupled. In particular, even a several scores of micron meters in deviation may be acceptable; the alignment accuracy along the optical axis may become substantially out of consideration. Accordingly, by carrying out the alignment for the lenses disposed opposite to the object to be coupled after the alignment for the lenses disposed in the side of the object to be coupled, the deviation inevitably caused in the lenses disposed in the side of the object to be coupled may be effectively compensated.

The present process first aligns and fixes four lenses, 14b, 15b, 23b, and 24b, disposed closer to the MMI devices, 40 and 50; then aligns and fixes rest of lenses, 14a, 15a, 23a, and 24a. In an alternative, when only one set of the optical source 112 and the optical connector 116 shown in FIG. 13B is prepared for two dummy connectors, 123a and 123b, the process may carry out the alignment and the fixation for the lenses using the test beam provided from one of the dummy connectors, 123a or 123b, then, perform the alignment and the fixation for the rest of lenses using the test beam provided from the other of the dummy connectors, 123a or 123b. Specifically, the process first aligns and fixes the lenses, 14b and 15b, then aligns and fixes the lenses, 14a and 15a, thereafter, the process aligns and fixes the lenses, 23b and 24b, then aligns and fixes the lenses, 23a and 24a. This procedure may reduce the count of the replacement of the optical source 112 and so on.

The procedure described above fixes the lenses disposed closer to the MMI devices, 40 and 50, at positions where the coupling efficiencies become respective maxima. In an alternative, those lenses are fixed at positions apart from the former positions described above, namely, offset from the former positions, and the lenses disposed relatively apart from the MMI devices, 40 and 50, may be fixed at positions where the coupling efficiencies become respective maxima. The position where the lens disposed closer alone gives a maximum coupling efficiency is different from a position where the lens disposed closer in a combination of two lenses gives a maximum coupling efficiency; the latter position becomes far from the object to be coupled compared with the former position.

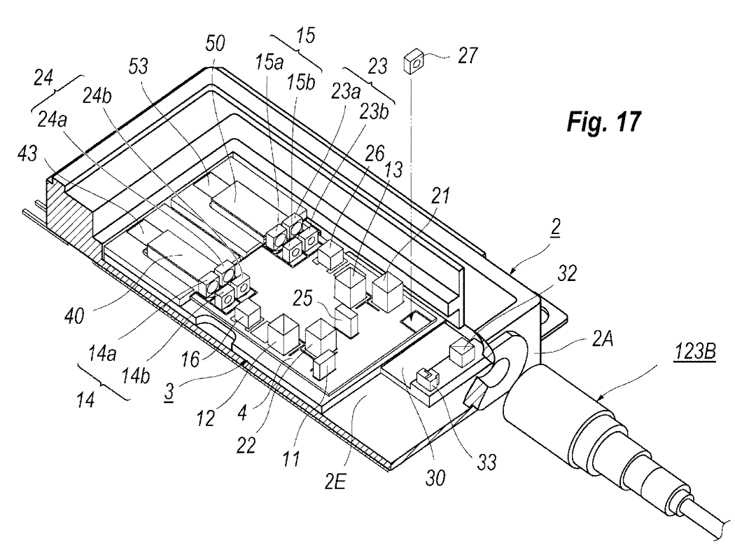

Thereafter, as FIG. 17 indicates, the process aligns and fixes the Sig light input lens 27. The Sig light input port 6 builds a concentrating lens therein, and the input lens 27 is aligned such that a focal point of the built-in lens coincides with a focal point of the input lens 27. Moreover, the VOA 31 in the extinction performance thereof may be enhanced by being disposed at a position of a beam waist formed between the built-in lens and the input lens 27, because the Sig light may pass the shutter of the VOA 31 that has a limited area. Accordingly, for aligning the input lens 27, another dummy connector 123B is preferably applied substituted from the dummy connector 123b, where the another dummy connector 123B includes a lens with a focal length equal to that of the built-in lens in the input port 6 for the Sig light. Thus, the present step replaces the dummy connector 123b with the dummy connector 123B.

Specifically, the process replaces the housing 2 with the reference reflector 104 on the stage 103 and the dummy connector 123b with the another dummy connector 123B as the connector 116 indicated in FIG. 13A. Then, using the manipulator 100 shown in FIG. 12, the process disposes the dummy connector 123B at the position where the Sig light input port 6 is to be attached, and faces the reflecting surface 104 of the reference reflector 104. Outputting the test beam from the dummy connector 123B, adjusting the position of the dummy connector 123B; the process aligns the optical axis of the dummy connector 123B such that the magnitude of the test beam detected by the power meter 115 becomes a maximum. Then, the test beam entering the housing 2 from the dummy connector 123B is adjusted in the polarization direction thereof by using the aforementioned test tool. That is, providing the test beam into the housing 2 through the dummy connector 123B, and detecting the magnitudes of respective polarization components split by the PBS in the test tool by the respective PDs, the polarization direction of the test beam provided through the polarization controller 113 is adjusted such that the two magnitudes thus detected becomes substantially equal to each other. Also, the process aligns the dummy connector 123B in a plane perpendicular to the optical axis by detecting the test beam providing from the dummy connector 123B into the housing 2 and sliding the dummy connector 123B to a direction where the magnitude detected by the PD 55 integrated within the MMI device 50 becomes greater. The alignment of the dummy connector 123B along the optical axis is completed by abutting the dummy connector 123B against the front wall 2A of the housing 2.

Thereafter, moving the input lens 27 on the designed position and providing the test beam coming from the dummy connector 123B to the input lens 27, the PD 55 built-in the MMI device 50 detects the magnitude of the test beam passing through the input lens 27. Slightly shifting the position of the input lens 27 along the front and rear, the left and right, and the up and down directions, a position may be determined where the built-in PD 55 generates a maximum output.

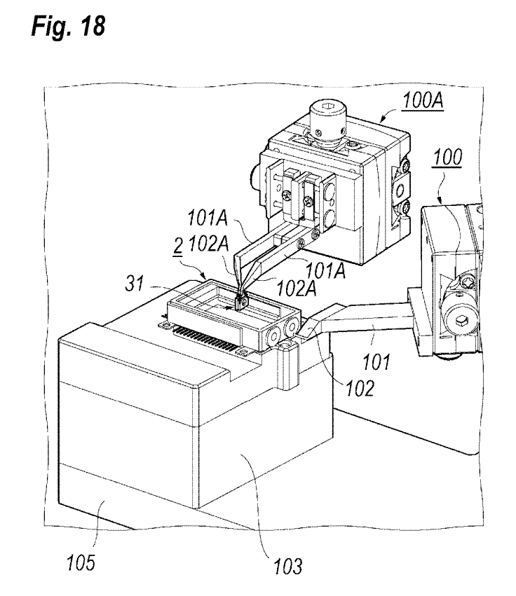

Then, as FIG. 18 indicates, the VOA 31 is mounted on the VOA carrier 30. In this step, the process disposes the VOA 31 on the pass of the test beam by securing the VOA 31 with a special manipulator 100A. The manipulator 100A provides two arms 101A each capable of optionally varying the position and the angle, specifically, translational positions along three axes perpendicular to each other, and rotation angles around two axes perpendicular to the optical axis of the VOA 31, and head secured in ends of the respective arms 101A. The VOA 31 is picked between the heads 102A. Concurrently, one of the heads 102A is electrically in contact with one of the electrodes of the VOA 31. The other head 102A is also electrically in contact with the other electrode of the VOA 31. Then, the VOA bias supply 120 provides the bias to the VOA 31 through the arms, 101A and 102A. Applying ultraviolet curable resin by a thickness of, for instance, greater than 100 μm, in advance to the mount, the VOA 31 is held above the surface of the VOA carrier 30 but apart by, for instance 100 μm. Altering the bias between 0 and 5 V with a period of, for instance, one (1) second, the bias is supplied to the VOA 31. Concurrently, sliding the VOA 31 along the direction parallel to the bottom 2E and perpendicular to the optical axis thereof, two PDs built-in the MMI devices, 40 and 50, may detect the magnitude of the respective components of the test beam attenuated by the VOA 31.

Then, the VOA 31 is fixed in a position where a difference in the magnitudes of two polarization components falls within an acceptable range. In this step, the difference in the outputs of the PDs built-in the MMI devices, 40 and 50, may be regarded as a difference in the attenuation of the polarization components of the test beam. The VOA 31 is mounted as tilting by a preset angle, for instance 7°, against the optical axis connecting the concentrating lens in the dummy connector 123B and the input lens 27 in order not to return the reflected beam back to the input port 6 of the Sig light.

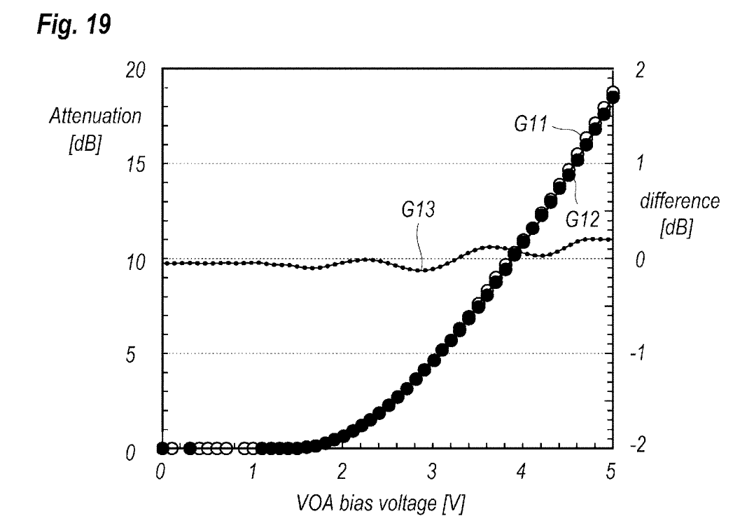

FIG. 19 shows an example of the attenuation by the VOA 31 against the bias applied thereto. Behaviors, G11 and G22, denotes the attenuation of the respective polarization components, where G11 corresponds to X-polarization, while, G12 corresponds to Y-polarization. A behavior G13 magnifies a difference of the attenuations. When the bias of 0V is applied, the VOA 31 is fully enclosed. As shown in FIG. 19, the attenuation increases as the bias increases; but even a common bias is applied, the attenuations of the respective polarization components becomes slightly different from each other. Moreover, the difference in the magnitudes of the polarization components increases as the bias increases. The present embodiment sets the difference of the attenuations for the respective polarization components to be within an acceptable range by aligning the VOA 31 along a direction of the optical axis, a direction perpendicular to the optical axis but parallel to the bottom 2E, and a direction perpendicular to the optical axis and to the bottom 2E. One example for the bias of 4.5V gives a condition that the attenuations for the respective polarization components exceeds 12 dB and a difference of the attenuations for the respective polarization components in a range of ±0.5 dB.

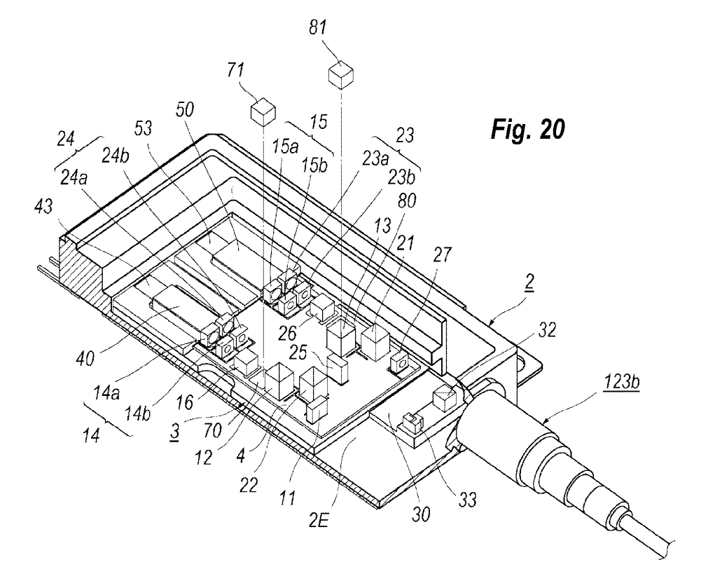

Thereafter, as shown in FIG. 20, two optical ATTs, 71 and 81, are mounted on the respective mounting area, 70 and 80. Specifically, the coherent receiver 1 is under a status where the PDs, 45 and 55, built-in the MMI devices, 40 and 50, may determine the magnitudes of two Lo light, L₁ and L₂, each split by the BS 21. Two Lo light, L₁ and L₂, split by the BS 21 couple with the MMI devices, 40 and 50, through respective optical paths, R₁ and R₂, different from each other. Depending on transmittance of the optical components disposed in the optical paths, R₁ and R₂, and the alignment with respect to the MMI devices, 40 and 50, the optical coupling efficiency becomes different from each other even when the BS 12 has the split ratio of 1:1. When the difference in the optical coupling efficiency becomes larger, the accuracy of the extraction of phase information contained in the Sig light by the MMI devices, 40 and 50, degrades.

Similarly, the Sig light N₀ reaches the MMI devices, 40 and 50, propagating on the optical paths, R₃ and R₄, different from each other split by the PBS 21. It would be hard to set the split ratio depending on the polarization to be exactly 1:1, and the optical components placed on the respective paths, R₃ and R₄, are not always equivalent to each other; accordingly, the coupling efficiency with respect to the MMI devices, 40 and 50, are unable to be same with each other. The coherent receiver 1 according to the present invention has a feature that, in order to compensate the difference of the coupling efficiencies against the MMI devices, 40 and 50, for the Lo light and the Sig light, the optical ATTs, 71 and 81, are disposed between the skew adjusting device 16 and the BS 12 on the path R₁ for the Lo light and between the skew adjusting device 26 and the PBS 21 on the path R₃ for the sign light, respective. Specific steps for mounting are, similar to those the BS 12 and PBS 21, first determining the angles of the optical ATTs, 71 and 81, using the visible laser light coming from the auto-collimator 125 and above the housing 2. Then, maintaining the angles, and mounting the optical ATTs, 71 and 81, on the respective designed areas, 70 and 80, the optical ATTs, 71 and 81, are fixed by the irradiation of the ultraviolet rays.

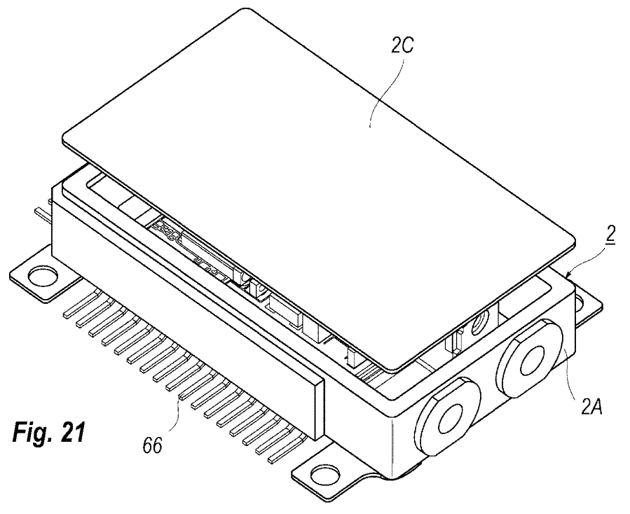

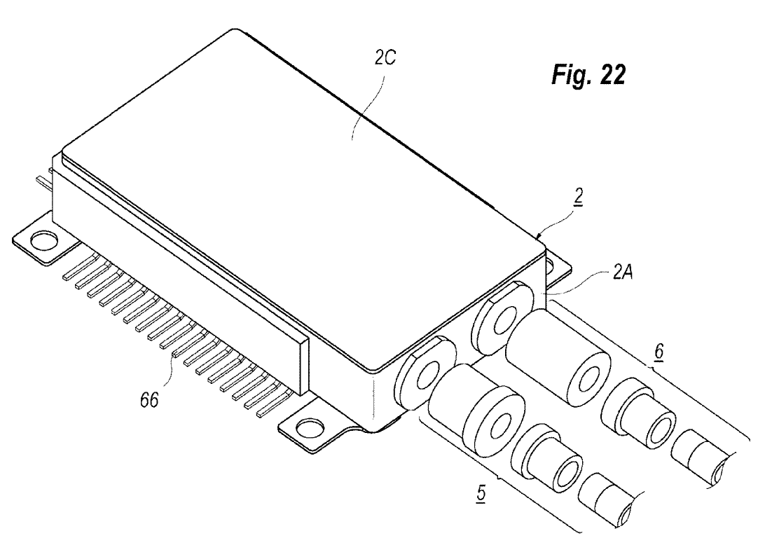

Thereafter, as FIG. 21 indicates, the lid 2C that covers the housing 2, may air-tightly seal the inside of the housing 2 by being attached thereto. Then, as FIG. 22 indicates, the process replaces the dummy connectors, 123a and 123b, with the Sig light input port 6 and the Lo light input port 5, and aligns and fixes the Sig light input port 6 and the Lo light input port 5. Specifically, providing a dummy signal light from the Sig light input port 6; the PD built-in the MMI device 40 detects the magnitude of this dummy Sig light. Referring to the detected magnitude and shifting the position of the Sig light input port, the process may determine the position of the Sig light input port 6 where the built-in PD gives a maximum output. As to the Lo light input port 5, similar to those for the Sig light input port 6, the process practically provides the Lo light, the PDs, 45 and 55, built-in the MMI devices, 40 and 50, may detect the magnitudes of thus provided Lo light. Shifting the position of the Lo light input port 5 as referring to the magnitudes of the detected Lo light may determine the position at which the built-in PDs, 45 and 55, generate the maximum outputs. After the determination, the Sig light input port 6 and the Lo light input port 5 are fixed to the housing 2. The YAG laser welding may be used for the fixation.

Next, advantages of the process for assembling the coherent receiver 1, according to the present invention will be described. The process of the present embodiment includes steps of: the first step of equalizing the magnitudes of the respective polarization components contained in the test beam that is prepared in advance thereto; the second step of, disposing the VOA 31 on the optical path of the test beams, monitoring the magnitudes of the two polarization components of the attenuated test beam as varying the attenuation of the VOA 31, and aligning the VOA 31; and the third step of fixing the VOA 31 at the position where the difference in the magnitudes of two polarization components of the test beam becomes within the preset range. According to the process, the attenuations of the two polarization components contained in the Sig light may be equalized to each other.

Also, like the present embodiment, the first step may include steps of disposing the dummy connector 123b that simulates the Sig light input port 6 at the position where the Sig light input port is to be assembled, providing the test beam within the coherent receiver 1 through the dummy connector 123b, and aligning the dummy connector 123b. According to the procedures above, the process may enhance the positional accuracy of the optical axis of the test beam and the alignment accuracy of the VOA 31.

Also, like the present embodiment, the second step may monitor the magnitudes of the two polarization components contained in the test beam by the PDs, 45 and 55, built-in the MMI devices, 40 and 50; and the third step regards the difference in the outputs of the PDs, 45 and 55, as the difference in the magnitudes of the two polarization components. According to the process thus described, the difference of the two polarization components may be detected.

Also, a conventional coherent receiver usually installs a VOA of a type of MEMS driving by a voltage signal. A VOA with the MEMS type has an aperture, a shutter size, of about 70 μm, which is relatively small. Accordingly, when the VOA is assembled in front of a PD, the VOA is assembled as visually inspecting the aperture through a microscope and aligning the aperture with the PD. However, the coherent receiver of the present embodiment disposes the VOA 31 not in front of the PD but between the optical components of the BS 12 and the input lens 27. Therefore, the present embodiment adequately adjusts the relative position of the shutter against the test beam as providing the test beam to the VOA 31 and dynamically opening and closing the shutter. The present embodiment provides the bias to the electrode of the VOA 31 through the manipulator 100A. Accordingly, the alignment of the VOA 31 may be easily carried out.

1. A coherent receiver that extracts phase information contained in signal light that has two polarization components by interfering between the signal light and local light, the coherent receiver comprising:
a polarization dependent beam splitter (PBS) that splits the signal light into two portions depending on the polarizations contained in the signal light;
a beam splitter (BS) that splits the local light into two portions;
a first multi-mode interference (MMI) device that interferes between one of the two portions of the signal light and another of the two portions of the local light;
a second MMI device that interferes between another of the two portions of the signal light and one of the two portions of the local light; and
at least one optical attenuator disposed on an optical path of the one of the two portions of the local light or an optical path of the one of the two portions of the signal light, the at least one optical attenuator attenuating the one of the two portions of the local light or the one of the two portions of the signal light.

2. The coherent receiver of claim 1,
wherein the another of the two portions of the local light enters the second MMI device through a first reflector, and
wherein the another of the two portions of the signal light enters the first MMI device through a second reflector.

3. The coherent receiver of claim 2,
wherein the PBS, the BS, the first reflector, and the second reflector are mounted on a base,
wherein the base provides a mounting area on the optical path of the one of the two portions of the local light or the optical path of the one of the two portions of the signal light, and
wherein the optical attenuator is mounted on the mounting area through an adhesive.

4. The coherent receiver of claim 3,
wherein the mount area is disposed between a pair of grooves provided in the base.

5. The coherent receiver of claim 3,
wherein the mounting area is disposed between a pair of mounds provided in the base.

6. The coherent receiver of claim 3,
wherein the mounting area provides a terrace that mounts the optical attenuator thereon.

7. The coherent receiver of claim 1,
wherein the at least one optical attenuator is provided on the optical path for the one of the two portions of the local light.

8. The coherent receiver of claim 1,
further including skew adjusting devices provided on the optical path of the one of the two portions of the local light and on the optical path of the one of the two portions of the local light.

9. The coherent receiver of claim 1,
wherein the one of the two portions of the local light, the another of the two portions of the local light, the one of the two portions of the signal light, and the another of the two portions of the signal light couple with the first MMI device and the second MMI device through respective first lenses and respective second lenses.

10. The coherent receiver of claim 1,
wherein the first MMI device includes two photodiodes each detecting a the one of the two portions of the local light and the another of the two portions of the signal light, and the second MMI device includes two photodiodes each detecting the another of the two portions of the local light and the one of the two portions of the signal light.

11. The coherent receiver of claim 1,
further including an optical attenuator that attenuates the signal light, the signal light being provided to the PBS through the optical attenuator.

12. The coherent receiver of claim 1,
further including a polarizer,
wherein the local light is provided to the BS through the polarizer.

13. The coherent receiver of claim 1,
further including a polarization rotator,
wherein the first MMI device interferes between the one of the two portions of the local light and the another of the two portions of the signal light whose polarization is rotated by 90° by the polarization rotator.
